(19) United States
(12) Patent Application Publication
(10) Pub. No.: US 2026/0361301 A1
(43) Pub. Date: Nov. 12, 2026

(54) CONTROLLER FOR BRIDGE CIRCUIT

(71) Applicant: Hon Hai Precision Industry Co., Ltd., New Taipei City (TW)

(72) Inventors: Surya Elangovan, New Taipei City (TW); Hao-Chung KUO, New Taipei City (TW); Yi-Kai HSIAO, New Taipei City (TW); Yu-Heng HONG, New Taipei City (TW); Tejender Singh Rawat, New Taipei City (TW); Chang-Ching TU, New Taipei City (TW)

(73) Assignee: Hon Hai Precision Industry Co., Ltd., New Taipei City (TW)

(21) Appl. No.: 19/204,591

(22) Filed: May 11, 2025

(51) Int. Cl. H03K 17/16; H02M 1/088

(52) U.S. Cl. CPC H03K 17/162; H02M 1/088

(57) ABSTRACT

A controller for a bridge circuit is provided. The controller includes a function circuit, a first control circuit, and a second control circuit. The function circuit generates a first light signal according to a first voltage level of a pulse width modulation signal, and generates a second light signal according to a second voltage level of the pulse width modulation signal. The first control circuit generates an upper arm control signal according to the first light signal, and provides the upper arm control signal to a control terminal of an upper arm switch. The second control circuit generates a lower arm control signal according to the second light signal, and provides the lower arm control signal to a control terminal of a lower arm switch.

### BACKGROUND

### Technical Field

The disclosure relates to a controller, and in particular to a controller for a bridge circuit.

### Description of Related Art

Generally, an upper arm switch and a lower arm switch of a bridge circuit may be controlled by a controller. To prevent shoot-through damage caused by the upper arm switch and the lower arm switch being turned on at the same time, the controller determines switching timing of the upper arm switch and the lower arm switch by using a function circuit. However, the upper arm switch and the lower arm switch receive a high-power power supply. The function circuit may malfunction due to interference from the high-power power supply of the bridge circuit, thereby increasing the risk of shoot-through damage occurring in the upper arm switch and the lower arm switch.

### SUMMARY

The disclosure provides a controller for a bridge circuit. The controller may reduce interference on a function circuit of the controller from a high-power power supply of the bridge circuit, thereby ensuring the correct operation of an upper arm switch and a lower arm switch.

In an embodiment of the disclosure, a controller includes a function circuit, a first control circuit, and a second control circuit. The function circuit generates a first light signal according to a first voltage level of a pulse width modulation signal and generates a second light signal according to a second voltage level of the pulse width modulation signal. The first control circuit is coupled to a control terminal of the upper arm switch of the bridge circuit. The first control circuit generates an upper arm control signal according to the first light signal and provides the upper arm control signal to the control terminal of the upper arm switch. The second control circuit is coupled to a control terminal of the lower arm switch of the bridge circuit. The second control circuit generates a lower arm control signal according to the second light signal and provides the lower arm control signal to the control terminal of the lower arm switch.

Based on the above, the first control circuit receives the first light signal from the function circuit and controls the upper arm switch according to the first light signal. The second control circuit receives the second light signal from the function circuit and controls the lower arm switch according to the second light signal. Optical communication transmission is performed between the function circuit, the first control circuit, and the second control circuit. Therefore, electrical isolation is present between the function circuit, the first control circuit, and the second control circuit. This way, interference on the function circuit from the high-power power supply of the bridge circuit may be reduced. Furthermore, the function circuit generates the first light signal according to the first voltage level of the pulse width modulation signal and generates the second light signal according to the second voltage level of the pulse width modulation signal. Therefore, the controller may prevent the upper arm switch and the lower arm switch from breakdown damage.

### BRIEF DESCRIPTION OF THE DRAWINGS

FIG. 1 is a schematic diagram of a controller according to an embodiment of the disclosure.

FIG. 2 is a schematic diagram of a controller according to an embodiment of the disclosure.

FIG. 3 is a signal timing diagram according to an embodiment of the disclosure.

FIG. 4 is a schematic diagram of a controller according to an embodiment of the disclosure.

FIG. 5 is an application schematic diagram according to an embodiment of the disclosure.

### DESCRIPTION OF THE EMBODIMENTS

Some embodiments of the disclosure will be described in detail below with reference to the drawings. For the reference numerals cited in the following description, when the same reference numerals appear in different drawings, the reference numerals will be regarded as referring to the same or similar elements. The embodiments are only a part of the disclosure and do not disclose all possible implementations of the disclosure. More specifically, the embodiments are merely examples in the claims of the disclosure.

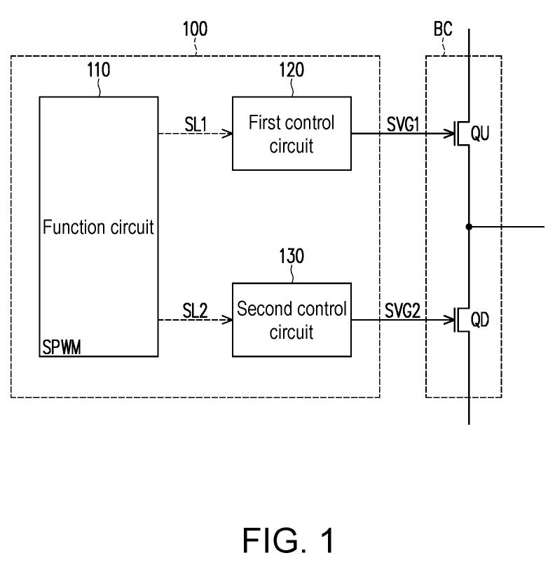

Referring to FIG. 1, FIG. 1 is a schematic diagram of a controller according to an embodiment of the disclosure. In this embodiment, a controller 100 is applicable to a bridge circuit BC in various application fields. The bridge circuit BC includes an upper arm switch QU and a lower arm switch QD. The bridge circuit BC may be a half-bridge circuit or a single-phase circuit in a three-phase bridge circuit.

In this embodiment, the controller 100 includes a function circuit 110, a first control circuit 120, and a second control circuit 130. The function circuit 110 generates a first light signal SL1 according to a first voltage level of a pulse width modulation signal SPWM and generates a second light signal SL2 according to a second voltage level of the pulse width modulation signal SPWM.

The first control circuit 120 is coupled to a control terminal of the upper arm switch QU of the bridge circuit BC. The first control circuit 120 generates an upper arm control signal SVG1 according to the first light signal SL1 and provides the upper arm control signal SVG1 to the control terminal of the upper arm switch QU. The second control circuit 130 is coupled to a control terminal of the lower arm switch QD of the bridge circuit BC. The second control circuit 130 generates a lower arm control signal SVG2 according to the second light signal SL2 and provides the lower arm control signal SVG2 to the control terminal of the lower arm switch QD.

It is noted that the first control circuit 120 receives the first light signal SL1 from the function circuit 110 and controls the upper arm switch QU according to the first light signal SL1. The second control circuit 130 receives the second light signal SL2 from the function circuit 110 and controls the lower arm switch QD according to the second light signal SL2. Optical communication transmission is performed between the function circuit 110, the first control circuit 120, and the second control circuit 130. Therefore, electrical isolation is present between the function circuit 110, the first control circuit 120, and the second control circuit 130. This way, interference on the function circuit 110 from the high-power power supply of the bridge circuit BC may be reduced.

Furthermore, the function circuit 110 generates a first light signal SL1 according to a first voltage level of a pulse width modulation signal SPWM and generates a second light signal SL2 according to a second voltage level of the pulse width modulation signal SPWM. This way, the controller 100 may prevent the upper arm switch QU and the lower arm switch QD from breakdown damage.

In this embodiment, the first voltage level may be a low voltage level. The second voltage level may be a high voltage level. The function circuit 110 generates the first light signal SL1 according to the low voltage level of the pulse width modulation signal SPWM and generates the second light signal SL2 according to the high voltage level of the pulse width modulation signal SPWM. In this embodiment, when the first light signal SL1 is generated, the upper arm control signal SVG1 has a high voltage value, and the lower arm control signal SVG2 has a low voltage value. On the other hand, when the second light signal SL2 is generated, the lower arm control signal SVG2 has a high voltage value, and the upper arm control signal SVG1 has a low voltage value. In other words, the controller 100 generates an upper arm control signal SVG1 with a high voltage value and a lower arm control signal SVG2 with a low voltage value according to the low voltage level of the pulse width modulation signal SPWM. The controller 100 generates an upper arm control signal SVG1 with a low voltage value and a lower arm control signal SVG2 with a high voltage value according to the high voltage level of the pulse width modulation signal SPWM.

In some embodiments, the first voltage level may be a high voltage level. The second voltage level may be a low voltage level. The function circuit 110 generates the first light signal SL1 according to the high voltage level of the pulse width modulation signal SPWM and generates the second light signal SL2 according to the low voltage level of the pulse width modulation signal SPWM. Therefore, the controller 100 may generate an upper arm control signal SVG1 with a high voltage value and a lower arm control signal SVG2 with a low voltage value according to the high voltage level of the pulse width modulation signal SPWM. The controller 100 generates an upper arm control signal SVG1 with a low voltage value and a lower arm control signal SVG2 with a high voltage value according to the low voltage level of the pulse width modulation signal SPWM.

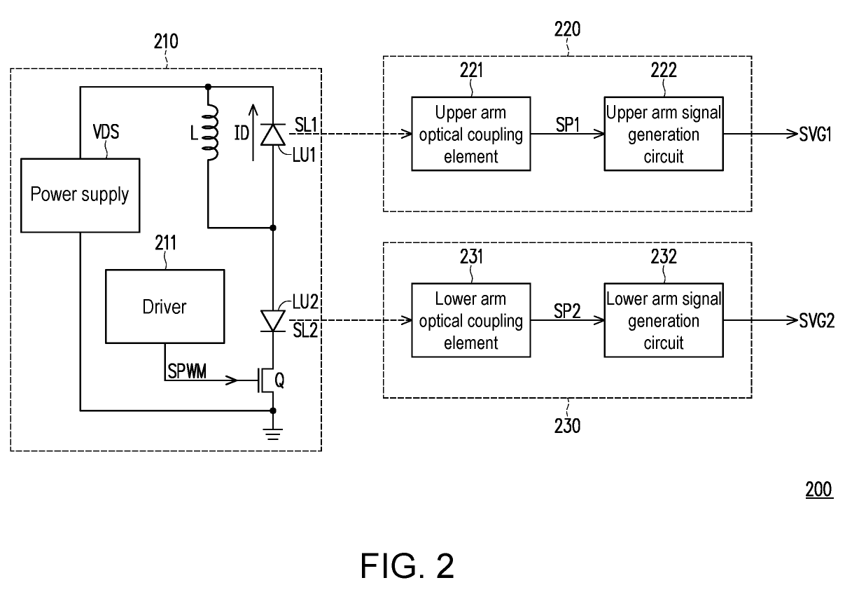

Referring to FIG. 2, FIG. 2 is a schematic diagram of a controller according to an embodiment of the disclosure. In this embodiment, a controller 200 includes a function circuit 210, a first control circuit 220, and a second control circuit 230. The function circuit 210 includes light output elements LU1 and LU2, an inductor L, and a control switch Q. The light output elements LU1 and LU2 may be implemented by light-emitting diodes (LEDs). A cathode of the light output element LU1 receives a reference high voltage. For example, a first terminal of the light output element LU1 receives the reference high voltage from a power supply VDS. An anode of the light output element LU2 is connected to an anode of the light output element LU1. The inductor L is connected between the cathode of the light output element LU1 and the anode of the light output element LU1. A first terminal of the control switch Q is connected to a cathode of the light output element LU2. A second terminal of the control switch Q receives a reference low voltage (e.g., ground). A control terminal of the control switch Q receives a pulse width modulation signal SPWM. In this embodiment, the control switch Q may be implemented by a transistor. For example, the control switch Q is implemented by a gallium nitride high electron mobility transistor (GaN HEMT), but the disclosure is not limited thereto. Therefore, the control switch Q may have a higher switching speed.

In this embodiment, the function circuit 210 further includes a driver 211. The driver 211 is connected to the control terminal of the control switch Q. The driver 211 generates the pulse width modulation signal SPWM.

In this embodiment, the first control circuit 220 includes an upper arm optical coupling element 221 and an upper arm signal generation circuit 222. The upper arm optical coupling element 221 provides an upper arm operating voltage SP1 in response to the first light signal SL1. The upper arm signal generation circuit 222 is connected to the upper arm optical coupling element 221. The upper arm signal generation circuit 222 provides an upper arm control signal SVG1 according to the upper arm operating voltage SP1.

In this embodiment, the second control circuit 230 includes a lower arm optical coupling element 231 and a lower arm signal generation circuit 232. The lower arm optical coupling element 231 provides a lower arm operating voltage SP2 in response to the second light signal SL2. The lower arm signal generation circuit 232 is connected to the lower arm optical coupling element 231. The lower arm signal generation circuit 232 provides a lower arm control signal SVG2 according to the lower arm operating voltage SP2.

In this embodiment, the upper arm optical coupling element 221 and the lower arm optical coupling element 231 may be implemented by a photodiode or a phototransistor. For example, the light output element LU1 and the upper arm optical coupling element 221 may be integrated into an optical coupling circuit. The light output element LU2 and the lower arm optical coupling element 231 may be integrated into another optical coupling circuit.

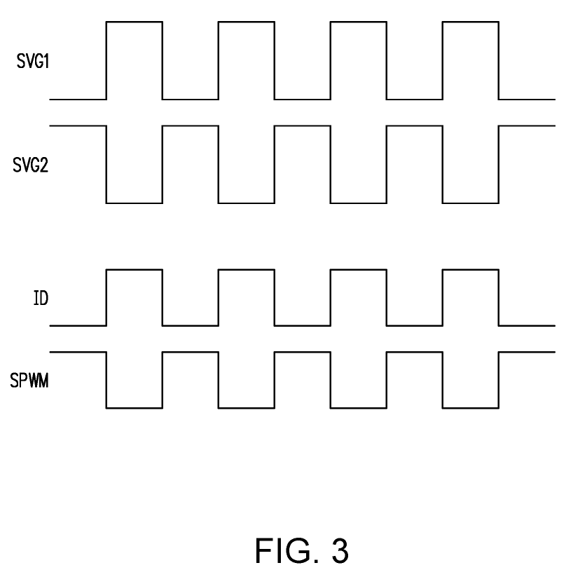

Referring to FIGS. 2 and 3, FIG. 3 is a signal timing diagram according to an embodiment of the disclosure. In this embodiment, the control switch Q may be an N-type GaN HEMT. Therefore, the control switch Q is turned on in response to the high voltage level of the pulse width modulation signal SPWM and is turned off in response to the low voltage level of the pulse width modulation signal SPWM.

When the control switch Q is turned on in response to the high voltage level of the pulse width modulation signal SPWM, the inductor L stores energy. When the control switch Q is turned on, the light output element LU1 is in a reverse bias state. An operating current ID flowing through the light output element LU1 is not generated. Therefore, the light output element LU1 stops outputting the first light signal SL1. Furthermore, when the control switch Q is turned on, the light output element LU2 is in a forward bias state. Therefore, the light output element LU2 outputs the second light signal SL2.

When the control switch Q is turned on, the lower arm optical coupling element 231 receives the second light signal SL2. The lower arm optical coupling element 231 provides a lower arm operating voltage SP2 with a high voltage value in response to the second light signal SL2, thereby causing the lower arm signal generation circuit 232 to provide a lower arm control signal SVG2 with a high voltage value. The upper arm optical coupling element 221 does not receive the first light signal SL1. Therefore, the upper arm optical coupling element 221 provides an upper arm operating voltage SP1 with a low voltage value, thereby causing the upper arm signal generation circuit 222 to provide an upper arm control signal SVG1 with a low voltage value.

When the control switch Q is turned off in response to the low voltage level of the pulse width modulation signal SPWM, the light output element LU2 stops outputting the second light signal SL2. When the control switch Q is turned off, the inductor L cannot store energy and generates a back electromotive force. The light output element LU1 may be in a forward bias state by using the back electromotive force. An operating current ID flowing through the light output element LU1 is generated. Therefore, the light output element LU1 outputs the first light signal SL1.

When the control switch Q is turned off, the upper arm optical coupling element 221 receives the first light signal SL1. The upper arm optical coupling element 221 provides an upper arm operating voltage SP1 with a high voltage value in response to the first light signal SL1, thereby causing the upper arm signal generation circuit 222 to provide an upper arm control signal SVG1 with a high voltage value. The lower arm optical coupling element 231 does not receive the second light signal SL2. Therefore, the lower arm optical coupling element 231 provides a lower arm operating voltage SP2 with a low voltage value, thereby causing the lower arm signal generation circuit 232 to provide a lower arm control signal SVG2 with a low voltage value.

In this embodiment, a duty cycle of the pulse width modulation signal SPWM may be adjusted. In some embodiments, a frequency of the pulse width modulation signal SPWM may be adjusted.

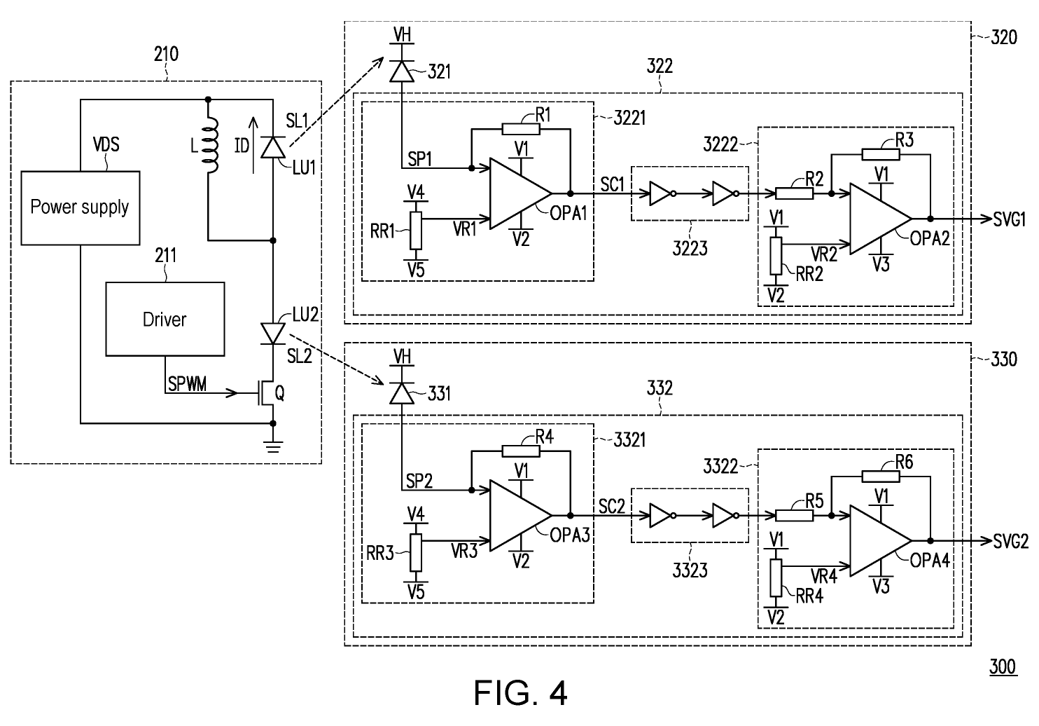

Referring to FIG. 4, FIG. 4 is a schematic diagram of a controller according to an embodiment of the disclosure. In this embodiment, a controller 300 includes the function circuit 210, a first control circuit 320, and a second control circuit 330. Implementation details of the function circuit 210 have already been clearly described in the embodiments of FIGS. 2 and 3 and are therefore not repeated here.

In this embodiment, the first control circuit 320 includes an upper arm optical coupling element 321 and an upper arm signal generation circuit 322. The upper arm optical coupling element 321 may be implemented by a photodiode. A cathode of the upper arm optical coupling element 321 receives a high voltage VH. A voltage value of the high voltage VH may be 15 volts, but the disclosure is not limited thereto. An anode of the upper arm optical coupling element 321 is connected to the upper arm signal generation circuit 322. The upper arm signal generation circuit 322 includes an upper arm comparator circuit 3221. The upper arm comparator circuit 3221 is connected to the upper arm optical coupling element 321. The upper arm comparator circuit 3221 receives an upper arm operating voltage SP1 and a reference voltage VR1 and generates an upper arm comparison signal SC1 according to a comparison result of the upper arm operating voltage SP1 and the reference voltage VR1. The upper arm signal generation circuit 322 provides an upper arm control signal SVG1 according to the upper arm comparison signal SC1.

In this embodiment, the upper arm signal generation circuit 322 further includes an upper arm gain circuit 3222. The upper arm gain circuit 3222 is connected to the upper arm comparator circuit 3221. The upper arm gain circuit 3222 gains (or shifts) a voltage value of the upper arm comparison signal SC1 to generate the upper arm control signal SVG1. For example, when the upper arm optical coupling element 321 receives the first light signal SL1, a voltage value of the upper arm operating voltage SP1 provided by the upper arm optical coupling element 321 is higher than the reference voltage VR1. Therefore, the upper arm comparator circuit 3221 provides the upper arm comparison signal SC1 with a high voltage value. The upper arm gain circuit 3222 adjusts the high voltage value level of the upper arm comparison signal SC1 to a first voltage value (e.g., 15 volts, but the disclosure is not limited thereto). When the upper arm optical coupling element 321 does not receive the first light signal SL1, a voltage value of the upper arm operating voltage SP1 provided by the upper arm optical coupling element 321 is lower than or equal to the reference voltage VR1. Therefore, the upper arm comparator circuit 3221 provides the upper arm comparison signal SC1 with a low voltage value. The upper arm gain circuit 3222 adjusts the low voltage value level of the upper arm comparison signal SC1 to a second voltage value (e.g., -5 volts, but the disclosure is not limited thereto).

For example, the upper arm comparator circuit 3221 includes an operational amplifier OPA1 (also referred to as a first upper arm operational amplifier) and a resistor R1 (also referred to as a first upper arm resistor). A first input terminal (also referred to as a positive input terminal) of the operational amplifier OPA1 receives the upper arm operating voltage SP1. A second input terminal (also referred to as a negative input terminal) of the operational amplifier OPA1 receives the reference voltage VR1 (also referred to as a first upper arm reference voltage). The resistor R1 is connected between the first input terminal and an output terminal of the operational amplifier OPA1. The operational amplifier OPA1 may be driven based on a high voltage V1 and a low voltage V2, but the disclosure is not limited thereto. A voltage value of the high voltage V1 may be, for example, 15 volts. A voltage value of the low voltage V2 may be, for example, 0 volts, but the disclosure is not limited thereto.

For example, the upper arm gain circuit 3222 includes an operational amplifier OPA2 (also referred to as a second upper arm operational amplifier) and resistors R2 and R3. A first terminal of the resistor R2 (also referred to as a second upper arm resistor) receives the upper arm comparison signal SC1. A second terminal of the resistor R2 is connected to a first input terminal of the operational amplifier OPA2. A second input terminal of the operational amplifier OPA2 receives a reference voltage VR2 (also referred to as a second upper arm reference voltage). The resistor R3 (also referred to as a third upper arm resistor) is connected between the first input terminal and an output terminal of the operational amplifier OPA2. The operational amplifier OPA2 may be driven based on the high voltage V1 and a low voltage V3. A voltage value of the low voltage V3 may be, for example, -5 volts, but the disclosure is not limited thereto.

For example, in this embodiment, the first input terminal of the operational amplifier OPA2 may be a positive input terminal. The second input terminal of the operational amplifier OPA2 may be a negative input terminal. The resistor R2 has an extremely low resistance value. The resistor R3 has an extremely high resistance value. Therefore, the upper arm gain circuit 3222 may function as a comparator. The upper arm gain circuit 3222 may generate the upper arm control signal SVG1 based on a comparison result of the upper arm comparison signal SC1 and the reference voltage VR2. As another example, in some embodiments, the first input terminal of the operational amplifier OPA2 may be a negative input terminal. The second input terminal of the operational amplifier OPA2 may be a positive input terminal. Therefore, the upper arm gain circuit 3222 may gain the upper arm comparison signal SC1 according to the resistance values of the resistors R2 and R3.

In this embodiment, the second control circuit 330 includes a lower arm optical coupling element 331 and a lower arm signal generation circuit 332. The lower arm optical coupling element 331 may be implemented by a photodiode. A cathode of the lower arm optical coupling element 331 receives a high voltage VH. An anode of the lower arm optical coupling element 331 is connected to the lower arm signal generation circuit 332. The lower arm signal generation circuit 332 includes a lower arm comparator circuit 3321. The lower arm comparator circuit 3321 is connected to the lower arm optical coupling element 331. The lower arm comparator circuit 3321 receives a lower arm operating voltage SP2 and a reference voltage VR3 and generates a lower arm comparison signal SC2 according to a comparison result of the lower arm operating voltage SP2 and the reference voltage VR2. The lower arm signal generation circuit 332 provides a lower arm control signal SVG2 according to the lower arm comparison signal SC2.

In this embodiment, the lower arm signal generation circuit 332 further includes a lower arm gain circuit 3322. The lower arm gain circuit 3322 is connected to the lower arm comparator circuit 3321. The lower arm gain circuit 3322 gains (or shifts) a voltage value of the lower arm comparison signal SC2 to generate the lower arm control signal SVG2. For example, when the lower arm optical coupling element 331 receives the second light signal SL2, a voltage value of the lower arm operating voltage SP2 provided by the lower arm optical coupling element 331 is higher than the reference voltage VR3. Therefore, the lower arm comparator circuit 3321 provides the lower arm comparison signal SC2 with a high voltage value. The lower arm gain circuit 3322 adjusts the high voltage value level of the lower arm comparison signal SC2 to a first voltage value (e.g., 15 volts, but the disclosure is not limited thereto). When the lower arm optical coupling element 331 does not receive the second light signal SL2, a voltage value of the lower arm operating voltage SP2 provided by the lower arm optical coupling element 331 is lower than or equal to the reference voltage VR3. Therefore, the lower arm comparator circuit 3321 provides the lower arm comparison signal SC2 with a low voltage value. The lower arm gain circuit 3322 adjusts the low voltage value level of the lower arm comparison signal SC2 to a second voltage value (e.g., -5 volts, but the disclosure is not limited thereto).

For example, the lower arm comparator circuit 3321 includes an operational amplifier OPA3 and a resistor R4. A first input terminal (also referred to as a positive input terminal) of the operational amplifier OPA3 receives the lower arm operating voltage SP2. A second input terminal (also referred to as a negative input terminal) of the operational amplifier OPA3 receives the reference voltage VR3. The resistor R4 is connected between the first input terminal and an output terminal of the operational amplifier OPA3. The operational amplifier OPA3 may be driven based on a high voltage V1 and a low voltage V2.

For example, the lower arm gain circuit 3322 includes an operational amplifier OPA4 and resistors R5 and R6. A first terminal of the resistor R5 receives the lower arm comparison signal SC2. A second terminal of the resistor R5 is connected to a first input terminal of the operational amplifier OPA4. A second input terminal of the operational amplifier OPA4 receives a reference voltage VR4. The resistor R6 is connected between the first input terminal and an output terminal of the operational amplifier OPA4. The operational amplifier OPA4 may be driven based on the high voltage V1 and a low voltage V3.

For example, in this embodiment, the first input terminal of the operational amplifier OPA4 may be a positive input terminal. The second input terminal of the operational amplifier OPA4 may be a negative input terminal. The resistor R5 has an extremely low resistance value. The resistor R6 has an extremely high resistance value. Therefore, the lower arm gain circuit 3322 may function as a comparator. The lower arm gain circuit 3322 may generate the lower arm control signal SVG2 based on a comparison result of the lower arm comparison signal SC2 and the reference voltage VR4. As another example, in some embodiments, the first input terminal of the operational amplifier OPA4 may be a negative input terminal. The second input terminal of the operational amplifier OPA4 may be a positive input terminal. Therefore, the lower arm gain circuit 3322 may gain the lower arm comparison signal SC2 according to the resistance values of the resistors R5 and R6 to generate the lower arm control signal SVG2.

Furthermore, in this embodiment, the upper arm signal generation circuit 322 further includes a delay circuit 3223. The delay circuit 3223 is connected between the upper arm comparator circuit 3221 and the upper arm gain circuit 3222. The delay circuit 3223 delays a timing of the upper arm comparison signal SC1. The lower arm signal generation circuit 332 further includes a delay circuit 3323. The delay circuit 3323 is connected between the lower arm comparator circuit 3321 and the lower arm gain circuit 3322. The delay circuit 3323 delays a timing of the lower arm comparison signal SC2. The delay circuits 3223 and 3323 respectively include the same number of inverters. For example, the delay circuits 3223 and 3323 respectively include two inverters, but the disclosure is not limited to the number of inverters. In some embodiments, the delay circuits 3223 and 3323 may be omitted.

It should be noted that the first control circuit 320 and the second control circuit 330 have similar circuit designs. Therefore, a voltage value of the reference voltage VR1 and a voltage value of the reference voltage VR3 are approximately similar. A voltage value of the reference voltage VR2 and a voltage value of the reference voltage VR4 are approximately similar. The lower arm comparison signal SC2 and the upper arm comparison signal SC1 are inverted relative to each other. Regardless of whether a gain of the upper arm gain circuit 3222 and the lower arm comparator circuit 3321 is a positive gain or a negative gain, the upper arm control signal SVG1 and the lower arm control signal SVG2 remain inverted relative to each other.

In some embodiments, the upper arm gain circuit 3222 and the lower arm comparator circuit 3321 may be omitted.

In this embodiment, the upper arm comparator circuit 3221 further includes a voltage divider resistor RR1 (also referred to as an upper arm voltage divider resistor). The voltage divider resistor RR1 is connected between a high voltage V4 and a low voltage V5. A voltage value of the high voltage V4 may be, for example, 5 volts. A voltage value of the low voltage V5 may be, for example, 0 volts. The voltage divider resistor RR1 generates the reference voltage VR1 according to a voltage division result of the high voltage V4 and the low voltage V5. A voltage value of the reference voltage VR1 is between the voltage value of the high voltage V4 and the voltage value of the low voltage V5. The upper arm gain circuit 3222 further includes a voltage divider resistor RR2. The voltage divider resistor RR2 is connected between a high voltage V1 and a low voltage V2. The voltage divider resistor RR2 generates the reference voltage VR2 according to a voltage division result of the high voltage V1 and the low voltage V2. A voltage value of the reference voltage VR2 is between the voltage value of the high voltage V1 and the voltage value of the low voltage V2. The lower arm comparator circuit 3321 further includes a voltage divider resistor RR3 (also referred to as an lower arm voltage divider resistor). The voltage divider resistor RR3 is connected between the high voltage V4 and the low voltage V5. The voltage divider resistor RR3 generates the reference voltage VR3 according to a voltage division result of the high voltage V4 and the low voltage V5. A voltage value of the reference voltage VR3 is between the voltage value of the high voltage V4 and the voltage value of the low voltage V5. The lower arm gain circuit 3322 further includes a voltage divider resistor RR4. The voltage divider resistor RR4 is connected between the high voltage V1 and the low voltage V2. The voltage divider resistor RR4 generates the reference voltage VR4 according to a voltage division result of the high voltage V1 and the low voltage V2. A voltage value of the reference voltage VR4 is between the voltage value of the high voltage V1 and the voltage value of the low voltage V2.

In some embodiments, the reference voltages VR1 to VR4 may be provided by an external circuit.

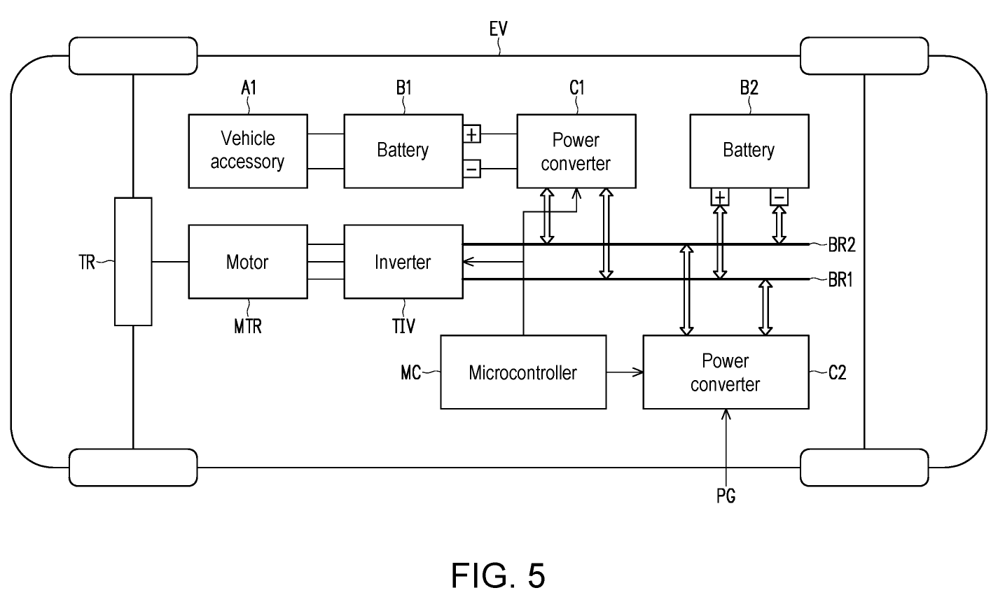

Referring to FIGS. 1 and 5, FIG. 5 is an application schematic diagram according to an embodiment of the disclosure. In this embodiment, the controller 100 is applied in the vehicle field. The controller 100 is applicable to an electric vehicle (EV). The electric vehicle EV includes a transmission mechanism TR, a motor MTR, a vehicle accessory A1, batteries B1 and B2, DC power buses BR1 and BR2, power converters C1 and C2, an inverter TIV, and a microcontroller MC.

A positive power terminal of the battery B2 is connected to the DC power bus BR1. A negative power terminal of the battery B2 is connected to the DC power bus BR2. The battery B2 may provide DC power. Therefore, the DC power bus BR1 transmits a high voltage value of the DC power (e.g., 800 volts). The DC power bus BR2 transmits a low voltage value of the DC power (e.g., 0 volts).

The inverter TIV is connected to the DC power buses BR1 and BR2 to receive DC power. The microcontroller MC controls the inverter TIV to convert the DC power into AC drive power. The motor MTR may be driven by the AC drive power, thereby driving the operation of the transmission mechanism TR. Therefore, the electric vehicle EV may move.

The power converter C1 is connected to the DC power buses BR1 and BR2. The microcontroller MC controls the power converter C1 to convert the DC power into a first battery power, thereby charging the battery B1 using the first battery power. The battery B1 may drive the vehicle accessory A1. The power converter C1 may be a DC-DC power converter.

The power converter C2 is connected to the DC power buses BR1 and BR2. The microcontroller MC controls the power converter C2 to receive an external power PG. The power converter C2 converts the external power PG into DC power and provides the DC power to the DC power buses BR1 and BR2. At this time, the battery B2 may be charged.

For example, the external power PG may be an AC power. Therefore, the power converter C2 may be an AC-DC power converter. As another example, the external power PG may be a DC power. Therefore, the power converter C2 may be a DC-DC power converter.

The control of the inverter TIV, the power converter C1, and the power converter C2 respectively includes a bridge circuit BC. Therefore, the controller 100 may control the operation of the bridge circuit BC of one of the inverter TIV, the power converter C1, and the power converter C2.

In summary, the first control circuit receives the first light signal from the function circuit and controls the upper arm switch according to the first light signal. The second control circuit receives the second light signal from the function circuit and controls the lower arm switch according to the second light signal. Optical communication transmission is performed between the function circuit, the first control circuit, and the second control circuit. Therefore, electrical isolation is present between the function circuit, the first control circuit, and the second control circuit. This way, interference on the function circuit from the high-power power supply of the bridge circuit may be reduced. Furthermore, the function circuit generates the first light signal according to the first voltage level of the pulse width modulation signal and generates the second light signal according to the second voltage level of the pulse width modulation signal. The first light signal and the second light signal are alternately generated. This way, the controller may prevent the upper arm switch and the lower arm switch from breakdown damage.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A controller for a bridge circuit, comprising:
a function circuit, configured to generate a first light signal according to a first voltage level of a pulse width modulation signal, and generate a second light signal according to a second voltage level of the pulse width modulation signal;
a first control circuit, coupled to a control terminal of an upper arm switch of the bridge circuit, and configured to generate an upper arm control signal according to the first light signal and provide the upper arm control signal to the control terminal of the upper arm switch; and
a second control circuit, coupled to a control terminal of a lower arm switch of the bridge circuit, and configured to generate a lower arm control signal according to the second light signal and provide the lower arm control signal to the control terminal of the lower arm switch.

2. The controller according to claim 1, wherein:
when the first light signal is generated, the upper arm control signal has a high voltage value, and the lower arm control signal has a low voltage value, and
when the second light signal is generated, the lower arm control signal has the high voltage value, and the upper arm control signal has the low voltage value.

3. The controller according to claim 1, wherein the function circuit comprises:
a first light output element, wherein a cathode of the first light output element receives a reference high voltage;
a second light output element, wherein an anode of the second light output element is connected to an anode of the first light output element;
an inductor, connected between the cathode of the first light output element and the anode of the first light output element; and
a control switch, wherein a first terminal of the control switch is connected to a cathode of the second light output element, a second terminal of the control switch receives a reference low voltage, and a control terminal of the control switch receives the pulse width modulation signal.

4. The controller according to claim 3, wherein the function circuit further comprises:
a driver, connected to the control terminal of the control switch, and configured to generate the pulse width modulation signal.

5. The controller according to claim 3, wherein:
when the control switch is turned on, the second light output element outputs the second light signal, and the first light output element stops outputting the first light signal, and
when the control switch is turned off, the first light output element outputs the first light signal, and the second light output element stops outputting the second light signal.

6. The controller according to claim 3, wherein the control switch is implemented by a gallium nitride high electron mobility transistor.

7. The controller according to claim 1, wherein the first control circuit comprises:
an upper arm optical coupling element, configured to provide an upper arm operating voltage in response to the first light signal; and
an upper arm signal generation circuit, connected to the upper arm optical coupling element, and configured to provide the upper arm control signal according to the upper arm operating voltage.

8. The controller according to claim 7, wherein the upper arm signal generation circuit comprises:
an upper arm comparator circuit, connected to the upper arm optical coupling element, and configured to receive the upper arm operating voltage and a reference voltage and generate an upper arm comparison signal according to a comparison result of the upper arm operating voltage and the reference voltage,
wherein the upper arm signal generation circuit provides the upper arm control signal according to the upper arm comparison signal.

9. The controller according to claim 8, wherein upper arm comparator circuit comprises:
a first upper arm operational amplifier, a first input terminal of the first upper arm operational amplifier receives the upper arm operating voltage, a second input terminal of the first upper arm operational amplifier receives a first upper arm reference voltage; and
a first upper arm resistor, connected between the first input terminal of the first upper arm operational amplifier and an output terminal of the first upper arm operational amplifier.

10. The controller according to claim 9, wherein upper arm comparator circuit further comprises:
an upper arm voltage divider resistor, connected between a high voltage and a low voltage, and configured to generate the first upper arm reference voltage according to a voltage division result of the high voltage and the low voltage.

11. The controller according to claim 8, wherein the upper arm signal generation circuit further comprises:
an upper arm gain circuit, connected to the upper arm comparator circuit, and configured to gain a voltage value of the upper arm comparison signal to generate the upper arm control signal.

12. The controller according to claim 11, wherein the upper arm gain circuit comprises:
a second upper arm resistor, a first terminal of the second upper arm resistor receives the upper arm comparison signal; and
a second upper arm operational amplifier, a first input terminal of the second upper arm operational amplifier is connected to a second terminal of the second upper arm resistor, a second input terminal of the second upper arm operational amplifier receives a second upper arm reference voltage; and
a third upper arm resistor, connected between the first input terminal of the second upper arm operational amplifier and an output terminal of the second upper arm operational amplifier,
wherein the upper arm gain circuit gains the upper arm comparison signal according to a resistance value of the second upper arm resistor and a resistance value of the third upper arm resistor,
wherein the resistance value of the second upper arm resistor is lower than the resistance value of the third upper arm resistor.

13. The controller according to claim 11, wherein the upper arm signal generation circuit further comprises:
an upper arm delay circuit, connected between the upper arm comparator circuit and the upper arm gain circuit, and configured to delay a timing of the upper arm comparison signal.

14. The controller according to claim 1, wherein the second control circuit comprises:
a lower arm optical coupling element, configured to provide a lower arm operating voltage in response to the second light signal; and
a lower arm signal generation circuit, connected to the lower arm optical coupling element, and configured to provide the lower arm control signal according to the lower arm operating voltage.

15. The controller according to claim 14, wherein the lower arm signal generation circuit comprises:
a lower arm comparator circuit, connected to the lower arm optical coupling element, and configured to receive the lower arm operating voltage and a reference voltage and generate a lower arm comparison signal according to a comparison result of the lower arm operating voltage and the reference voltage,
wherein the lower arm signal generation circuit provides the lower arm control signal according to the lower arm comparison signal.

16. The controller according to claim 15, wherein lower arm comparator circuit comprises:
a first lower arm operational amplifier, a first input terminal of the first lower arm operational amplifier receives the lower arm operating voltage, a second input terminal of the first lower arm operational amplifier receives a first lower arm reference voltage; and
a first lower arm resistor, connected between the first input terminal of the first lower arm operational amplifier and an output terminal of the first lower arm operational amplifier.

17. The controller according to claim 16, wherein lower arm comparator circuit further comprises:
a lower arm voltage divider resistor, connected between a high voltage and a low voltage, and configured to generate the first lower arm reference voltage according to a voltage division result of the high voltage and the low voltage.

18. The controller according to claim 15, wherein the lower arm signal generation circuit further comprises:
a lower arm gain circuit, connected to the lower arm comparator circuit, and configured to gain a voltage value of the lower arm comparison signal to generate the lower arm control signal.

19. The controller according to claim 18, wherein the lower arm gain circuit comprises:
a second lower arm resistor, a first terminal of the second lower arm resistor receives the lower arm comparison signal; and
a second lower arm operational amplifier, a first input terminal of the second lower arm operational amplifier is connected to a second terminal of the second lower arm resistor, a second input terminal of the second lower arm operational amplifier receives a second lower arm reference voltage; and
a third lower arm resistor, connected between the first input terminal of the second lower arm operational amplifier and an output terminal of the second lower arm operational amplifier,
wherein the lower arm gain circuit gains the lower arm comparison signal according to a resistance value of the second lower arm resistor and a resistance value of the third lower arm resistor,
wherein the resistance value of the second lower arm resistor is lower than the resistance value of the third lower arm resistor.

20. The controller according to claim 18, wherein the lower arm signal generation circuit further comprises:
a lower arm delay circuit, connected between the lower arm comparator circuit and the lower arm gain circuit, and configured to delay a timing of the lower arm comparison signal.
